(19) United States
(12) Patent Application Publication
(10) Pub. No.: US 2023/0314953 A1
(43) Pub. Date: Oct. 5, 2023

(54) METHODS TO IMPROVE PROCESS WINDOW AND RESOLUTION FOR DIGITAL LITHOGRAPHY WITH AUXILIARY FEATURES

(71) Applicant: Applied Materials, Inc., Santa Clara, CA (US)

(72) Inventors: Chi-Ming TSAI, San Jose, CA (US); Thomas L. LAIDIG, Richmond, CA (US); Douglas Joseph VAN DEN BROEKE, Sunnyvale, CA (US); Jang Fung CHEN, Cupertino, CA (US)

(21) Appl. No.: 18/006,259

(22) PCT Filed: Sep. 16, 2021
(86) PCT No.: PCT/US2021/050660

§ 371 Date: Jan. 20, 2023

Related U.S. Application Data
(60) Provisional application No. 63/080,303, filed on Sep. 18, 2020.

(51) Int. Cl. G03F 7/20

(52) U.S. Cl. CPC G03F 7/2057; G03F 7/70508; G03F 7/70291; G03F 7/70441

(57) ABSTRACT

Embodiments described herein relate to methods of printing features within a lithography environment. The methods include determining a mask pattern. The mask pattern includes auxiliary features to be provided with main features to a maskless lithography device in a lithography process. The auxiliary features are determined with a rule-based process flow or a lithography model process flow.

### BACKGROUND

### Field

Embodiments of the present disclosure generally relate to lithography systems. More particularly, embodiments of the present disclosure relate to methods of printing features within a lithography environment.

### Description of the Related Art

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels may include a layer of liquid crystal material forming pixels disposed between two plates. When power from a power supply is applied across the liquid crystal material, an amount of light passing through the liquid crystal material may be controlled at pixel locations enabling images to be generated.

Lithography techniques are generally employed to create electrical features incorporated as part of the liquid crystal material layer forming the pixels. Maskless lithography techniques involve creating a virtual mask, and selected portions of films are removed from the films to create patterns in films on substrates. However, as device sizes decreases, there remains a need for improved resolutions.

### SUMMARY

In one embodiment, a method is provided. The method includes receiving data defining one or more main features for a lithographic process. The main features include one or more polygons. The method further includes determining a position and a width of one or more auxiliary features based on the data defining the main features and determining a pattern bias to be applied for the main features during the lithographic process. The pattern bias of the main features is determined based on the position and the width of the auxiliary features. The method further includes converting the data corresponding to the main features, the auxiliary features, and the pattern bias to a virtual mask file and patterning a substrate using the virtual mask file in a maskless lithography device.

In another embodiment, a method is provided. The method includes receiving data defining one or more main features for a lithographic process. The main features include one or more polygons. The method further includes inputting the data to a lithography model constructed to predict an aerial image and resist profile based on the data and determining a position and a width of one or more auxiliary features using numerical calculations to solve the lithography model, wherein the position and the width determined correspond to a maximum intensity log-slope (ILS) or depth-of-focus of the main features formed in a photoresist of a substrate based on the data. The method further includes determining a pattern bias to be applied for the main features during the lithographic process. The pattern bias of the main features is determined using numerical calculations to solve the lithography model, wherein the pattern bias determined corresponds to a maximum ILS or depth-of-focus of the main features formed in the photoresist of the substrate based on the data. The method further includes converting the data corresponding to the main features, the auxiliary features, and the pattern bias to a virtual mask file and patterning a substrate using the virtual mask file in a maskless lithography device.

In yet another embodiment, a system is provided. The system includes a moveable stage configured to support a substrate having a photoresist disposed thereon and a processing unit disposed over the moveable stage configured to print a virtual mask provided by a controller in communication with the processing unit. The controller is configured to receive data defining one or more main features for a lithographic process. The main features include one or more polygons. The controller is further configured to determine a position and a width of one or more auxiliary features based on the data defining the main features and determine a pattern bias to be applied for the main features during the lithographic process. The pattern bias of the main features is determined based on the position and the width of the auxiliary features. The controller is further configured to convert the data corresponding to the main features, the auxiliary features, and the pattern bias to a virtual mask file and pattern a substrate using the virtual mask file with the processing unit.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic diagram of a lithography environment according to embodiments described herein.

FIG. 2 is a perspective view of an exemplary maskless lithography device according to embodiments described herein.

FIGS. 3A and 3B are schematic views of a mask pattern of a digital pattern file according to embodiments described herein.

FIGS. 4A-4D are schematic views of configurations of mask patterns according to embodiments described herein.

FIG. 5 is a flow diagram of a method for performing a rule-based exposure according to embodiments described herein.

FIG. 6 is a schematic view of a rule-based process flow according to embodiments described herein.

FIG. 7 is a flow diagram of a method for performing a model based exposure according to embodiments described herein.

FIG. 8 is a schematic view of a model-based process flow according to embodiments described herein.

FIG. 9 depicts a processing system according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to lithography systems. More particularly, embodiments of the present disclosure relate to methods of printing features within a lithography environment. The methods include determining a mask pattern. The mask pattern includes auxiliary features to be provided with main features to a maskless lithography device in a lithography process. The auxiliary features are determined with a rule-based process flow or a lithography model process flow.

In one embodiment, a method is provided. The method includes receiving data defining one or more main features for a lithographic process. The main features include one or more polygons. The method further includes determining a position and a width of one or more auxiliary features based on the data defining the main features and determining a pattern bias to be applied for the main features during the lithographic process. The pattern bias of the main features is determined based on the position and the width of the auxiliary features. The method further includes converting the data corresponding to the main features, the auxiliary features, and the pattern bias to a virtual mask file and patterning a substrate using the virtual mask file in a maskless lithography device.

In another embodiment, a method is provided. The method includes receiving data defining one or more main features for a lithographic process. The main features include one or more polygons. The method further includes inputting the data to a lithography model constructed to predict an aerial image and resist profile based on the data and determining a position and a width of one or more auxiliary features using numerical calculations to solve the lithography model, wherein the position and the width determined correspond to a maximum intensity log-slope (ILS) or depth-of-focus of the main features formed in a photoresist of a substrate based on the data. The method further includes determining a pattern bias to be applied for the main features during the lithographic process. The pattern bias of the main features is determined using numerical calculations to solve the lithography model, wherein the pattern bias determined corresponds to a maximum ILS or depth-of-focus of the main features formed in the photoresist of the substrate based on the data. The method further includes converting the data corresponding to the main features, the auxiliary features, and the pattern bias to a virtual mask file and patterning a substrate using the virtual mask file in a maskless lithography device.\ In yet another embodiment, a system is provided. The system includes a moveable stage configured to support a substrate having a photoresist disposed thereon and a processing unit disposed over the moveable stage configured to print a virtual mask provided by a controller in communication with the processing unit. The controller is configured to receive data defining one or more main features for a lithographic process. The main features include one or more polygons. The controller is further configured to determine a position and a width of one or more auxiliary features based on the data defining the main features and determine a pattern bias to be applied for the main features during the lithographic process. The pattern bias of the main features is determined based on the position and the width of the auxiliary features. The controller is further configured to convert the data corresponding to the main features, the auxiliary features, and the pattern bias to a virtual mask file and pattern a substrate using the virtual mask file with the processing unit.

In yet another embodiment, a system is provided. The system includes a moveable stage configured to support a substrate having a photoresist disposed thereon and a processing unit disposed over the moveable stage configured to print a virtual mask provided by a controller in communication with the processing unit. The controller is configured to receive data defining one or more main features for a lithographic process. The main features include one or more polygons. The controller is further configured to determine a position and a width of one or more auxiliary features based on the data defining the main features and determine a pattern bias to be applied for the main features during the lithographic process. The pattern bias of the main features is determined based on the position and the width of the auxiliary features. The controller is further configured to convert the data corresponding to the main features, the auxiliary features, and the pattern bias to a virtual mask file and pattern a substrate using the virtual mask file with the processing unit.

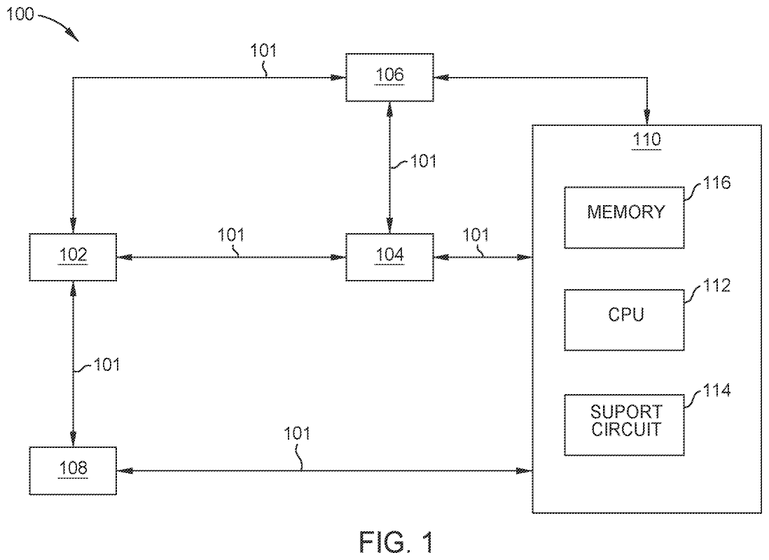

FIG. 1 is a schematic diagram of a lithography environment 100. As shown, the lithography environment 100 includes, but is not limited to, a maskless lithography device 108, a controller 110, and communication links 101. The controller 110 is operable to facilitate the transfer of a digital pattern file 104 (e.g., data) provided to the controller 110. The controller 110 is operable to execute a virtual mask software application 102 and a pattern modification software application 106. Each of the lithography environment devices is operable to be connected to each other via the communication links 101. Each of the lithography environment devices is operable to be connected to the controller 110 by the communication links 101. The lithography environment 100 can be located in the same area or production facility, or the each of the lithography environment devices can be located in different areas. In some instances, one or more of the virtual mask software application 102, the digital pattern file 104, and/or pattern modification software application 106 may be stored locally on the controller 110 (e.g., on memory 116). Additionally or alternatively, one or more of the virtual mask software application 102, the digital pattern file 104, and/or pattern modification software application 106 may be stored remotely (e.g., on the cloud).

Each of the plurality of lithography environment devices are additionally indexed with method 500 operations and method 700 operations described herein. In one embodiment, which can be combined with other embodiments described herein, each of the maskless lithography device 108 and the controller 110 include an on-board processor and memory, where the memory is configured to store instructions corresponding to any portion of the methods 500 and 700 described below. The communication links 101 may include at least one of wired connections, wireless connections, satellite connections, and the like. The communications links 101 facilitate sending and receiving files to store data, according to embodiments further described herein. Transfer of data along communications links 101 can include temporarily or permanently storing files or data in the cloud, before transferring or copying the files or data to a lithography environment device.

The controller 110 includes a central processing unit (CPU) 112, support circuits 114 and a memory 116. The CPU 112 can be one of any form of computer processor that can be used in an industrial setting for controlling the lithography environment devices. The memory 116 is coupled to the CPU 112. The memory 116 can be one or more of readily available memory, such as random access memory (RAM), read only memory (ROM), floppy disk, hard disk, or any other form of digital storage, local or remote. The support circuits 114 are coupled to the CPU 112 for supporting the processor. These circuits include cache, power supplies, clock circuits, input/output circuitry, subsystems, and the like. The controller 110 can include the CPU 112 that is coupled to input/output (I/O) devices found in the support circuits 114 and the memory 116. The controller 110 is operable to facilitate and transfer the digital pattern file 104 to the maskless lithography device 108 via the communication links 101. The digital pattern file 104 is operable to be provided to the virtual mask software application 102 or the maskless lithography device 108 via the controller 110.

The memory 116 can include one or more software applications, such as the virtual mask software application 102 and the pattern modification software application 106. The memory 116 can also include stored media data that is used by the CPU 112 to perform the method 500 and 700 described herein. The CPU 112 can be a hardware unit or combination of hardware units capable of executing software applications and processing data. In some configurations, the CPU 112 includes a digital signal processor (DSP), an application-specific integrated circuit (ASIC), and/or a combination of such units. The CPU 112 is configured to execute the one or more software applications, such as the virtual mask software application 102 and the pattern modification software application 106 and process the stored media data, which can be each included within the memory 116. The controller 110 controls the transfer of data and files to and from the various lithography environment devices. The memory 116 is also configured to store instructions corresponding to any operation of the method 500 or the method 700 according to embodiments described herein.

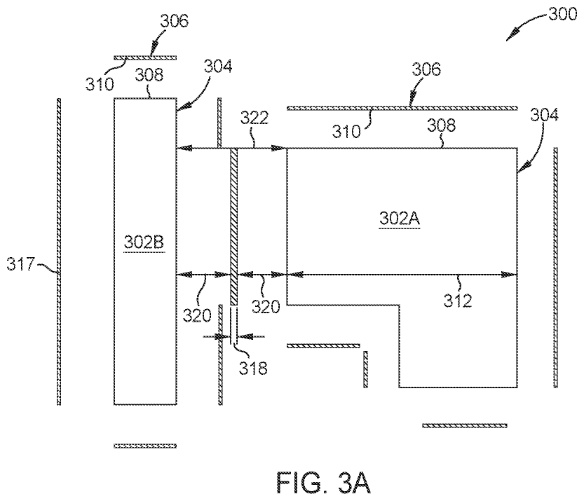

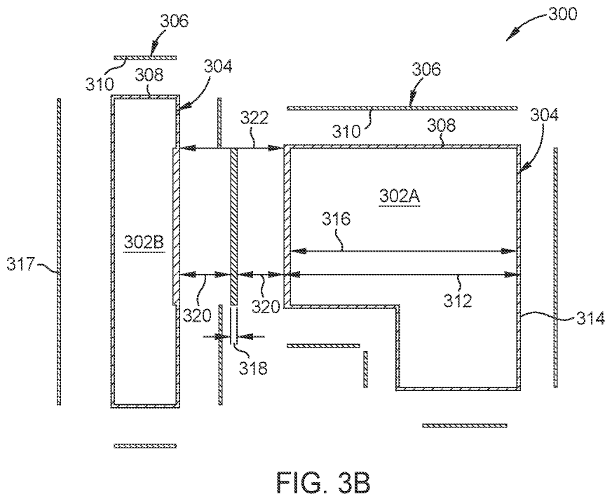

The controller 110 is operable to receive pattern features (shown in FIGS. 3A-3B) of the digital pattern file 104 and transfer the pattern features to the maskless lithography device 108 via the communication links 101. The controller 110 may also facilitate the control and automation of a digital lithography process based on the digital pattern file 104 provided by the pattern modification software application 106. The digital pattern file 104 (or computer instructions), which may be referred to as an imaging design file, readable by the controller 110, determines which tasks are performable on a substrate. While the virtual mask software application 102 and the pattern modification software application 106 are illustrated as separate from the controller 110 (e.g., in the cloud), it is contemplated that the virtual mask software application 102 and the pattern modification software application 106 may be stored locally (e.g., in memory 116).

The digital pattern file 104 corresponds to a pattern to be written into the photoresist using electromagnetic radiation output by the maskless lithography device 108. In one embodiment, which can be combined with other embodiments described herein, the pattern may be formed with one or more patterning devices. For example, the one or more patterning devices are configured to perform ion-beam etching, reactive ion etching, electron-beam (e-beam) etching, wet etching, nanoimprint lithography (NIL), and combinations thereof. The digital pattern file 104 may be provided in different formats. For example, the format of the digital pattern file 104 may be one of a GDS format, and an OASIS format, among others. The digital pattern file 104 includes information corresponding to features to be printed based on the pattern features contained in the digital pattern file 104. The printed features are to be generated on a substrate (e.g., the substrate 220). The digital pattern file 104 may include areas of interest which correspond to one or more structural elements. The structural elements may be constructed as geometrical shapes (e.g., polygons).

The pattern modification software application 106 is executable to modify and/or update the digital pattern file 104. In one embodiment, which can be combined with other embodiments described herein, the pattern modification software application 106 is a software program stored in the memory 116 of the controller 110. The CPU 112 is configured to execute the software program. In another embodiment, which can be combined with other embodiments described herein, the pattern modification software application 106 may be a remote computer server which includes a controller and a memory (e.g., data store).

The digital pattern file 104 is provided to the controller 110. The controller 110 applies the pattern modification software application 106 to the digital pattern file 104. For example, the pattern modification software application 106 may be applied remotely or locally. The pattern modification software application 106 is operable to modify and update the digital pattern file 104 by including one or more auxiliary features 306 (shown in FIGS. 3A and 3B) adjacent to one or more main features 304 (shown in FIGS. 3A and 3B). In one embodiment, which can be combined with other embodiments described herein, the pattern modification software application 106 utilizes a rule-based algorithm for application of the one or more auxiliary features 306. The rule-based algorithm utilizes a lookup table to determine a position and a width of the auxiliary features 306 to be included in the digital pattern file 104.

The lookup table includes empirical data relating to positions and dimensions of the main features 304 (shown in FIGS. 3A and 3B). The rule-based algorithm references the lookup table to determine the position and the width of the auxiliary features 306 (shown in FIGS. 3A and 3B) that maximize an intensity log-slope (ILS) and depth-of-focus of printed features formed in a photoresist of a substrate based on the digital pattern file 104. The rule-based algorithm further references the lookup table to determine a pattern bias to apply to the main features 304 (shown in FIGS. 3A and 3B). The lookup table includes empirical data relating to the biasing of the main features 304 required to maintain desired dimensions for the main features 304 (shown in FIGS. 3A and 3B) based on a position and a width of the auxiliary features 306 (shown in FIGS. 3A and 3B).

The rule-based algorithm is constructed empirically by designing a set of test features and printing the test features, and correlating tests with a resultant ILS value. For example, for an isolated test feature with a critical dimension of 1 μm, multiple auxiliary features with different widths are created and placed at various locations for each 1 μm test feature. The pattern bias may also be added to the test feature set as a variable. The test feature set is printed and inspected. The results with the largest ILS and/or depth of focus, correct dimensions of the test feature set, and with no extra printed patterns, are added to the lookup table. Thus, the lookup table includes rows of data denoting the position and width of the auxiliary features to achieve the largest possible ILS and depth of focus (or other values, based on user-defined rules) based on the provided digital pattern file 104. In some examples, the software algorithms defined here in may not select the auxiliary features with the absolute largest ILS value from the lookup table. Rather, the software algorithm may select the auxiliary feature with the largest ILS value that also meets any other predefined condition. In such an example, the software algorithm may select the auxiliary feature with the second, third, or other largest ILS value if other auxiliary features do not satisfy other rules of the algorithm.

In subsequent printing operations, when the pattern modification software application 106 detects an isolated main feature 304 with a critical dimension of 1 μm, the auxiliary features and pattern bias are determined by referencing the lookup table. Each row of the lookup table may correspond to one type of main feature. For example, the lookup table may include a single row for a 1 μm width isolated main feature, and another row for a 1 μm width main features with 3 μm polygon spacing between adjacent main features. Other examples, variables, and values are contemplated. It is contemplated that up table and/or selection may be refined or updated in response to processing results.

In another embodiment, which can be combined with other embodiments described herein, the pattern modification software application 106 utilizes a lithography model. The lithography model analyzes the digital pattern file 104 to enlarge an intensity log-slope (ILS) and depth-of-focus of features formed in a photoresist of a substrate.

The lithography model is a physics based model. The lithography model may use either a scalar or vector imaging model. For example, the lithography model may utilize Transmission Cross Coefficients (TCC) which is a matrix defined by optical properties and/or photoresist properties. Other numerical simulation techniques such as Resolution Enhancement Technology (RET), Optical Proximity Correction (OPC), and Source Mask Optimization (SMO) may be utilized. However, all such models and modeling techniques, whether now known or later developed, are intended to be within the scope of the present disclosure. The lithography model is constructed to be defined based on optical properties (e.g., optical properties relating to the maskless lithography device 108) and the photoresist properties (e.g., properties of the photoresist of which the pattern will be printed on such as materials and processing characteristics of the photoresist). The photoresist properties include numerical aperture, exposure, illumination type, size of illumination, and wavelength and may include other values.

Once the lithography model is constructed, the digital pattern file 104 is input to the lithography model. The lithography model then outputs a prediction of the aerial image and resist profile of the digital pattern file 104. Through post-processing operations, the ILS and depth of focus of features formed in a photoresist of a substrate based on the digital pattern file 104 may be determined. The lithography model will utilize numerical calculations to predict variables to achieve the maximum ILS and depth of focus (or a maximum ILS and depth of focus within other predefined constraints). The variables includes a width 318 and position 320 of auxiliary features 306 (shown in FIGS. 3A and 3B) and a pattern bias value of the main features 304 (shown in FIG. 3B). The numerical calculations may be iterative methods, level-set methods, or any other numerical methods operable to solve the lithography model.

In one embodiment, the lithography model refines the digital pattern file 104 by iteratively adjusting the variables of the digital pattern file 104. The variables are determined within predefined constraints. The predefined constraints include ensuring that no extra features are printed and the main features have the desired dimensions outlined in the digital pattern file. The variables are iteratively adjusted according to the lithography model or other rules of the pattern modification software application 106 until a threshold intensity log-slope (ILS) and/or depth-of-focus of printed features are achieved. Additionally or alternatively, the pattern modification software application 106 refines the digital pattern file 104 by iteratively adjusting the variables of the digital pattern file 104 according to an algorithm or other rules of the pattern modification software application 106 until a maximum intensity log-slope (ILS) and/or depth-of-focus of features are achieved. The lithography model also ensures that the width of the auxiliary features 306 are not large enough to enable the auxiliary features 306 to be printed. The lithography model ensures that the bias is applied such that the main feature 304 is within tolerances of the desired pattern based on the digital pattern file 104.

The digital pattern file 104 may be provided to the virtual mask software application 102 after updating the digital pattern file 104 with the pattern modification software application 106. The controller 110 provides the digital pattern file 104 to the virtual mask software application 102. The virtual mask software application 102 is operable to receive the digital pattern file 104 via the communication links 101. The virtual mask software application 102 can be a vMASC software. In one embodiment, which can be combined with other embodiments described herein, the virtual mask software application 102 is a software program stored in the memory 116 of the controller 110. The CPU 112 is configured to execute the software program. In another embodiment, which can be combined with other embodiments described herein, the virtual mask software application 102 may be a remote computer server which includes a controller and a memory (e.g., data store).

The digital pattern file 104 is converted into a virtual mask file by the virtual mask software application 102. The virtual mask file is a digital representation of the design to be printed by the maskless lithography device 108. The virtual mask file is provided to the maskless lithography device 108 via the communication links 101. In one embodiment, which can be combined with other embodiments described herein, the virtual mask file may be stored locally in the maskless lithography device 108.

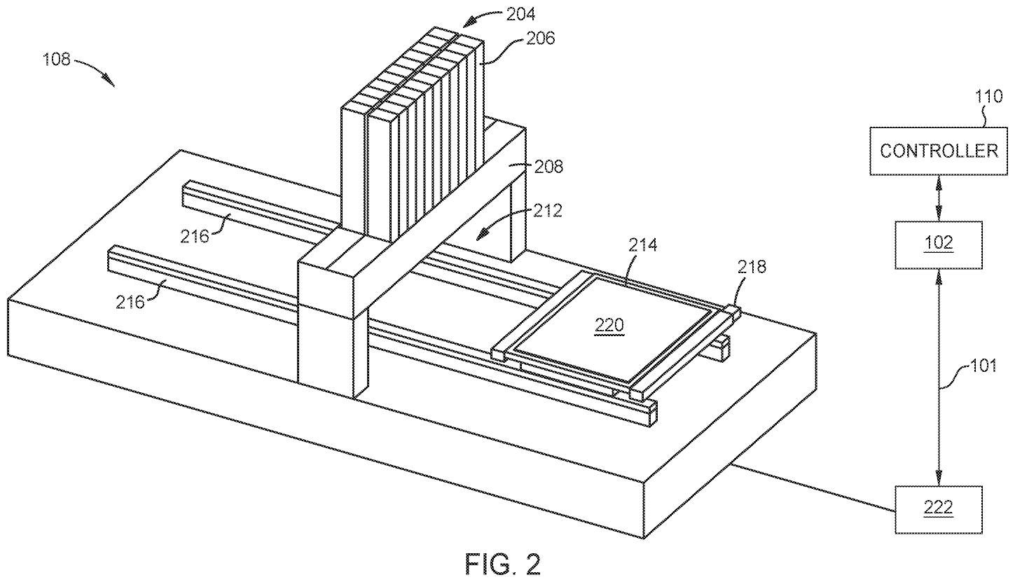

FIG. 2 is a perspective view of an exemplary maskless lithography device 108. The maskless lithography device 108 includes a stage 214 and a processing unit 204. The stage 214 is supported by a pair of tracks 216. A substrate 220 is supported by the stage 214. The stage 214 is operable to move along the pair of tracks 216. An encoder 218 is coupled to the stage 214 in order to provide information of the location of the stage 214 to a lithography controller 222. The maskless lithography device 108 is in communication with a controller 110. The controller 110 is operable to deliver one or more virtual mask files corresponding to the mask pattern or otherwise configured to perform processes described herein.

The lithography controller 222 is generally designed to facilitate the control and automation of the processing techniques described herein. The lithography controller 222 may be coupled to or in communication with the processing unit 204, the stage 214, and the encoder 218. The processing unit 204 and the encoder 218 may provide information to the lithography controller 222 regarding the substrate processing and the substrate aligning. For example, the processing unit 204 may provide information to the lithography controller 222 to alert the lithography controller 222 that substrate processing has been completed. The lithography controller 222 facilitates the control and automation of a maskless lithography process based on a virtual mask file provided by a virtual mask software application 102. The virtual mask file, readable by the lithography controller 222, determines which tasks are to be performed on a substrate. The virtual mask file corresponds to an exposure pattern to be written into the photoresist using the electromagnetic radiation.

The substrate 220 comprises any suitable material, for example, glass, which is used as part of a flat panel display. In other embodiments, which can be combined with other embodiments described herein, the substrate 220 is made of other materials capable of being used as a part of the flat panel display. The substrate 220 has a film layer to be patterned formed thereon, such as by pattern etching thereof, and a photoresist layer formed on the film layer to be patterned, which is sensitive to electromagnetic radiation, for example UV or deep UV “light”. A positive photoresist includes portions of the photoresist, when exposed to radiation, are respectively soluble to a photoresist developer applied to the photoresist after the pattern is written into the photoresist using the electromagnetic radiation. A negative photoresist includes portions of the photoresist, when exposed to radiation, will be respectively insoluble to photoresist developer applied to the photoresist after the pattern is written into the photoresist using the electromagnetic radiation. The chemical composition of the photoresist determines whether the photoresist is a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. After exposure of the photoresist to the electromagnetic radiation, the resist is developed to leave an exposure underlying film layer. Then, using the patterned photoresist, the underlying thin film is pattern etched through the openings in the photoresist to form a portion of the electronic circuitry of the display panel.

The processing unit 204 is supported by the support 208 such that the processing unit 204 straddles the pair of tracks 216. The support 208 provides an opening 212 for the pair of tracks 216 and the stage 214 to pass under the processing unit 204. The processing unit 204 is a pattern generator configured to receive the virtual mask file from the virtual mask software application 102. The virtual mask file is provided to the processing unit 204 via the lithography controller 222. The processing unit 204 is configured to expose the photoresist in the maskless lithography process using one or more image projection systems 206. The one or more image projection systems 206 are operable to project write beams of electromagnetic radiation to the substrate 220. The exposure pattern generated by the processing unit 204 is projected by the image projection systems 206 to expose the photoresist of the substrate 220 to the exposure pattern.

The exposure of the photoresist forms one or more different printed features in the photoresist. In one embodiment, which can be combined with other embodiments described herein, each image projection system 206 includes a spatial light modulator to modulate the incoming light to create the desired image. The spatial light modulators may include, but are not limited to, digital micromirrors, liquid crystal displays (LCDs), liquid crystal over silicon (LCoS) devices, ferroelectric liquid crystal on silicon (FLCoS) devices, microshutters, microLEDs, VCSELs, liquid crystal displays (LCDs), or any solid state emitter of electromagnetic radiation. In one embodiment, which can be combined with other embodiments described herein, the image projection system 206 utilizes digital micromirror devices (DMDs), which are an example of spatial light modulators, to project write beams of electromagnetic radiation to the substrate 220. The DMDs are used as reflective digital light switches in a variety of applications used to project images on the photoresist, thereby exposing and printing the printed features on the photoresist. The DMDs generally includes several hundred thousand to millions of microscopic mirrors (“micromirrors”) arranged in a rectangular array. Each micromirror corresponds to a single pixel of the image to be printed and can be tilted at various angles about a hinge.

Each micromirror may be in an “ON” position or an “OFF” position based on the digital pattern file 104 (shown in FIG. 1). When the light reaches the DMD, the micromirrors that are in the “ON” position project a plurality of write beams to a projection lens (not shown). The projection lens then projects the write beams to the substrate 220. Each adjacent micromirror of the DMD has a 180-degree phase difference. The light is illuminated onto the DMD obliquely. The angle is determined such that the difference of the length of optical paths of adjacent mirrors is half of the wavelength and thus a 180-degree phase difference is produced. The 180-degree phase difference between adjacent mircromirrrors produces a dark space between each write beam. Regions of the printed features which include a high density of write beams, i.e., the inner portions of the printed features include a 180-degree phase shift. Thus, these regions may have a higher normalized intensity log-slope (ILS) than the left-most and right-most regions the printed features. The left-most and right-most write beams of the have a lower normalized ILS due to the lack of an adjacent micromirror to construct a 180-degree interference which generally would produce a sharp image contrast. Increasing normalized ILS enlarges the process window and a larger depth-of-focus enlarges the focus window of a pattern to be formed. Thus, as the process window and the focus window are increased, the maskless lithography device 108 can print higher resolution patterns and improve the resolution limit. In one embodiment, which can be combined with other embodiments described herein, the resolution is less than about 0.8 μm. As the write beams are projected in accordance with the digital pattern file 104 and it is beneficial to increase ILS and the depth-of-focus auxiliary features may be added to form a 180-degree phase shift with the edge of the main features.

FIG. 3A is a schematic view of a mask pattern 300 of a digital pattern file 104. The mask pattern 300 is designed to enlarge an intensity log-slope (ILS) and depth-of-focus of features formed in a photoresist of a substrate 220 (shown in FIG. 2). The digital pattern file 104 may include one or more polygons 302A-302B. For example, FIG. 3A shows a first polygon 302A and a second polygon 302B. The one or more polygons 302A and 302B correspond to portions of the photoresist to be exposed to electromagnetic radiation projected by a processing unit 204 (shown in FIG. 2). Improving the ILS of features to be formed in a photoresist that correspond to the one or more polygons 302A and 302B of the digital pattern file 104 will improve the resolution limitations of one or more image projection systems 206 (shown in FIG. 2).

Although only two polygons 302A and 302B are shown in FIG. 3A and 3B, the number of polygons are not limited. It is to be understood that any shaped polygons could be used for the one or more polygons 302A and 302B, such that one or more different features may be formed in the photoresist. The mask pattern 300 is applicable to be utilized on all pattern types as well as bright and dark field exposures.

The first polygon 302A and the second polygon 302B each include a main feature 304 and one or more auxiliary features 306. The main feature 304 includes the main pattern to be printed. In order to improve the intensity log-slope (ILS) and the depth-of-focus of the main feature 304, the auxiliary features 306 are added. The auxiliary features 306 are included such that a 180-degree phase interference is constructed between the auxiliary features and a main feature edge 308 of the main features 304. The ILS corresponds to the fidelity of the features and the process window of the printing process. For example, a lower ILS corresponds to a smaller process window. The ILS is improved when the main feature edge 308 of the main feature 304 runs parallel with an auxiliary edge 310 of the main feature 304, as shown in FIG. 3A. In some embodiments, which can be combined with other embodiments described herein, the main feature edge 308 is not parallel with the auxiliary edge 310.

The auxiliary features 306 each have a width 318 and a position 320. The width 318 of the auxiliary features 306 may be different along different auxiliary edges 310. Increasing the width 318 of the auxiliary edges 310 increases the ILS, however the width 318 of the auxiliary features 306 is smaller than the critical dimension 312. Each auxiliary edge 310 is parallel to a corresponding main feature edge 308. The position 320 of the auxiliary features 306 is defined as the distance between the auxiliary edges 310 and the corresponding main feature edge 308. An auxiliary feature length 317 may be refined as needed to align with the corresponding main feature edge 308.

In one embodiment, which can be combined with other embodiments described herein, the width 318 and the position 320 of the auxiliary features 306 are refined depending on a critical dimension 312 of the main feature 304, polygon spacing 322, and/or orientation of the main feature 304. The width of the auxiliary features 306 must be smaller than the critical dimension 312, such that the auxiliary feature 306 is not printed. Additionally, adjacent auxiliary features 306 must each have the position 320 sufficiently apart such that the auxiliary features 306 are not printed. Auxiliary features 306 with positions 320 that are not sufficiently separated will be printed. Due to diffraction, the area where the substrate (e.g., the substrate 220) receives the light dose from the auxiliary features 306 is slightly larger than the area defined by the auxiliary features 306. When two auxiliary features 306 are too close to each other, the middle regions of the two auxiliary features 306 receive an increased light dose and therefore may print on the substrate, altering the desired pattern outlined in the virtual mask file.

The position 320 of the auxiliary features 306 will be such that the auxiliary features 306 and the main features 304 are separated by more than a threshold distance. If the threshold distance is not exceeded, the auxiliary features 306 may be printed in the subsequent lithography process. Thus, the auxiliary features 306 should have the position 320 such that the threshold distance is exceeded. The polygon spacing 322 is defined as the distance between adjacent polygons 302A and 302B. The polygon spacing 322 will affect the position 320 of each of the auxiliary features 306. The mask pattern 300 is refined and updated with the auxiliary features 306 having the width 318 and the position 320 such that the auxiliary features 306 will not be printed. Thus, depending on the polygon spacing 322, one or more auxiliary features 306 may be positioned between the adjacent main features 304 to improve the ILS without being printed. In one embodiment, which can be combined with other embodiments described herein, as shown in FIG. 3A, the width 318 of the auxiliary features 306 may be increased to improve the ILS of the main feature edges 308. One auxiliary feature 306 may also improve the ILS of the main feature edges 308 for the first polygon 302A and the second polygon 302B. Additionally, the orientation of the main feature 304 may affect the position 320 and/or the width 318 of the auxiliary features 306. As the DMD is not circularly symmetric, vertical main features 304 will be printed differently from a 45-degree oriented main feature 304 due to how the features are quantized by the DMD.

FIG. 3B is a schematic view of a mask pattern 300 of a digital pattern file 104. FIG. 3B shows the main feature 304 of the mask pattern 300 with a pattern bias 314. Due to the auxiliary features 306, dimensions of the main feature 304 will increase or decrease. After light is illuminated on each of the auxiliary features 306 and the main features 304, an electrical field is generated. The electrical field has polarity and if the two electrical fields have the same polarity, intensity increases and the dimensions of the main features 304 increase. When the polarity is different, the intensity and dimensions of the main features 304 decrease.

To compensate for the change of the dimensions of the main features 304, the pattern bias 314 will be implemented on the main features 304. The pattern bias 314 consists of either increasing or decreasing the critical dimension 312 of the main features 304 to get a biased critical dimension 316 prior to the addition of the auxiliary features 306. Thus, when the dimensions of the main features increase or decrease, the biased critical dimension 316 will shift to the desired critical dimension 312. The pattern bias 314 may be either a positive bias or a negative bias (i.e., increase or decrease the critical dimension 312 to achieve the biased critical dimension 316). The pattern bias 314 is implemented such that the critical dimension 312 is achieved after the effects of the auxiliary features 306. As shown in FIG. 3B, the pattern bias 314 is a positive bias and is applied to the main feature 304 such that a biased critical dimension 316 is larger than the critical dimension 312. Therefore, the biased critical dimension 316 will reduce to the critical dimension 312 during the lithography process. The pattern bias 314 enables the critical dimension 312 to be achieved despite the auxiliary features 306. The pattern bias 314 can be refined through simulation or experiment.

The behavior of the pattern bias 314 is sensitive to the position 320 of the auxiliary features 306. As the width 318 of the auxiliary features 306 keeps increasing, the auxiliary features 306 will be moved from the desired position 320 and may lead to negligible or negative effects to the ILS. In some embodiments, the width 318 of the auxiliary features 306 corresponds to the amount of pattern bias 314. For example, as increasing the width 318 increases the ILS, the critical dimension 312 will correspondingly be reduced. Therefore, the pattern bias 314 will be increased to compensate for the reduction of the critical dimension 312. The critical dimension 312 should be within tolerances allowed based on the digital pattern file 104.

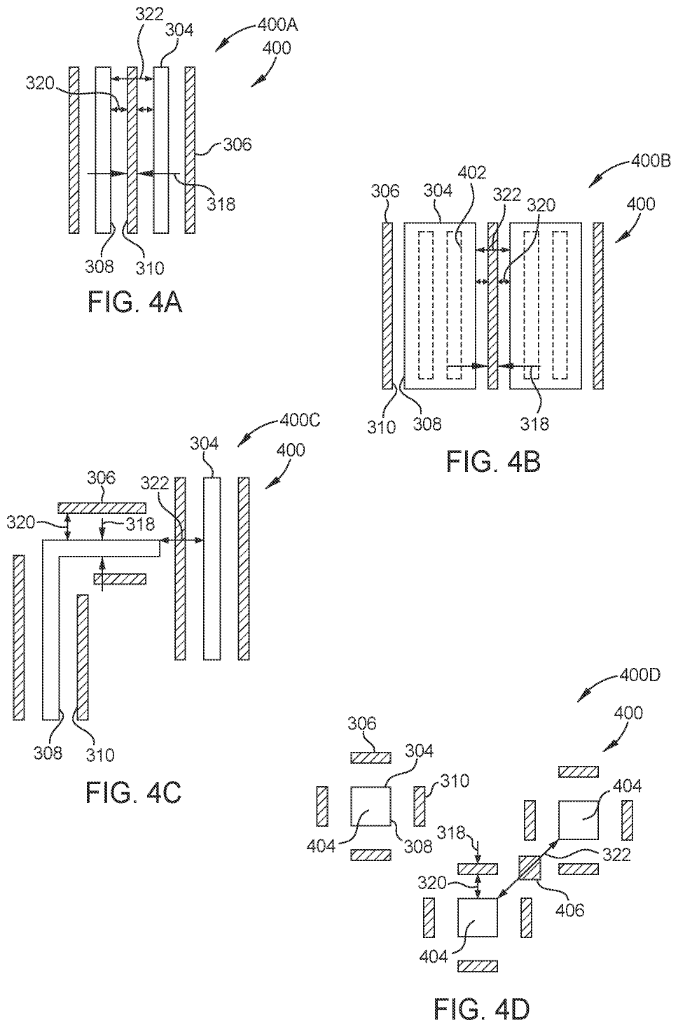

FIGS. 4A-4D are schematic views of configurations of mask patterns 400A-400D. Each configuration 400A-400B includes one or more main features 304 and one or more auxiliary features 306. FIG. 4A depicts a first configuration 400A of the mask pattern 400. The first configuration 400A includes alternating auxiliary features 306 and main features 304. Although only one auxiliary feature 306 is disposed between the two main features 304, the number of auxiliary features 306 are not limited. For example, there may be no auxiliary features 306 disposed between the main features 304. In another example, two auxiliary features are disposed between the main features 304. The number of auxiliary features 306 is determined based on the polygon spacing 322 between the main features 304. The auxiliary features 306 have a position 320 and a width 318 operable to maximize a normalized intensity log-slope (ILS) and depth-of-focus along main feature edges 308.

FIG. 4B depicts a second configuration 400B of the mask pattern 400. The second configuration 400B includes one or more anti-auxiliary features 402 disposed in the main features 304. The auxiliary features 306 are disposed between the main features 304. The anti-auxiliary features 402 are disposed between the main features 304. Due to diffraction, the electrical field contributed (or deducted) by the anti-auxiliary features 402 is a sinc (sin(x)/x) function, i.e., the electrical field has sidelobes. Thus, the slope of the electrical field alternates between positive and negative polarity in a direction away from the anti-auxiliary features 402. When the distance between the anti-auxiliary feature 402 and the main features 304 is optimal, the slope of electrical field of the anti-auxiliary feature 402 will enhance the ILS of main features 304.

Although only one auxiliary feature 306 is disposed between the two main features 304, the number of auxiliary features 306 are not limited. For example, there may be no auxiliary features 306 disposed between the main features 304. In another example, two auxiliary features are disposed between the main features 304. The number of auxiliary features 306 is determined based on the polygon spacing 322 between the main features 304. Additionally, the anti-auxiliary features 402 are not limited, and there may be any number of anti-auxiliary features 402 in the main features 304. The auxiliary features 306 have a position 320 and a width 318 operable to maximize a normalized intensity log-slope (ILS) and depth-of-focus along main feature edges 308.

FIG. 4C depicts a third configuration 400C of the mask pattern 400. The third configuration 400C depicts a 2-dimensional mask pattern. The third configuration 400C includes the auxiliary features 306 disposed around the main features 304. The auxiliary features 306 have a position 320 and a width 318 operable to maximize a normalized intensity log-slope (ILS) and depth-of-focus along main feature edges 308.

FIG. 4D depicts a fourth configuration 400D of the mask pattern 400. The fourth configuration 400D depicts a mask pattern with a plurality of vias 404. The plurality of vias 404 are surrounded by the auxiliary features 306. In some embodiments, an intermediate auxiliary feature 406 may be disposed between two the vias 404. The intermediate auxiliary feature 406 may be included in the mask pattern 400D to maximize a normalized intensity log-slope (ILS) and depth-of-focus along main feature edges 308. The auxiliary features 306 have a position 320 and a width 318 operable to maximize a normalized intensity log-slope (ILS) and depth-of-focus along main feature edges 308.

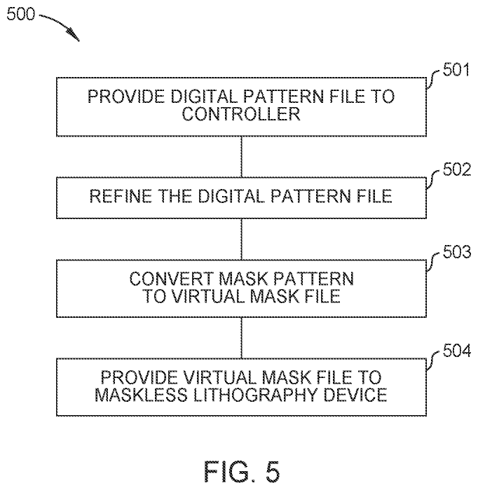

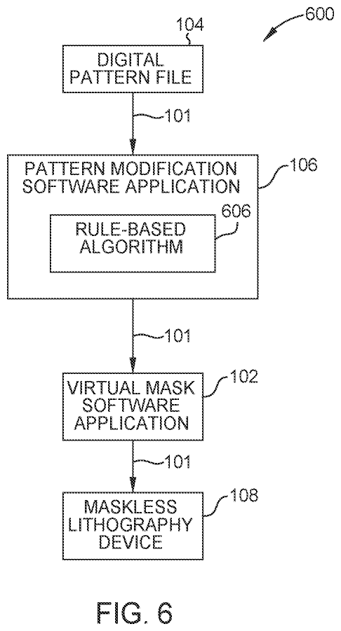

FIG. 5 is a flow diagram of a method 500 for performing a rule-based exposure as shown in FIG. 5. FIG. 6 is a schematic view of a rule-based process flow 600. FIG. 5 includes elements of the lithography environment 100 shown in FIG. 1. To facilitate explanation, the method 500 will be described with reference to the rule-based process flow 600 of FIG. 6 and the mask pattern 300 of FIGS. 3A and 3B. In one embodiment, which can be combined with other embodiments described herein, the method 500 may be utilized with any lithography process and any maskless lithography device. The controller 110 is operable to facilitate the transfer of a digital pattern file 104 (e.g., data). The controller 110 is operable to facilitate operations of the method 500.

At operation 501, a digital pattern file 104 is provided to a controller 110. The controller 11 is operable to execute a pattern modification software application 106. The digital pattern file 104 corresponds to a pattern to be written into a photoresist using electromagnetic radiation output by the maskless lithography device 108 (shown in FIG. 2). The digital pattern file 104 may include areas of interest which correspond to one or more structural elements. The structural elements may be constructed as geometrical shapes, such as polygons (e.g., polygons 302A and 302B shown in FIGS. 3A-3B). The digital pattern file 104 initially defines one or more main features 304 (shown in FIGS. 3A-3B).

At operation 502, the digital pattern file 104 is refined with the pattern modification software application 106. The digital pattern file 104 is refined to determine the position 320 and width 318 of one or more auxiliary features 306 and a pattern bias 314 of the main features 304. The digital pattern file 104 is refined to improve the intensity-log-slope (ILS) of features to be formed on the photoresist in a lithography process. In one embodiment, which can be combined with other embodiments described herein, the ILS is specifically refined along main feature edges 308 of the main features 304. The digital pattern file 104 is refined and updated by the pattern modification software application 106 to form a mask pattern 300. The pattern modification software application 106 determines the auxiliary features 306 based on a rule-based algorithm 606. The rule-based algorithm 606 utilizes a lookup table to implement the auxiliary features 306 of the digital pattern file 104.

As described above, the lookup table may be constructed by categorizing different main features 304 of the digital pattern file 104 into groups and applying different auxiliary features 306 to each main feature 304, and thereafter determining and correlating resulting ILS and/or depth of focus values. For example, for repeating main features 304, such as the mask pattern 400 shown in FIG. 4A, the main features 304 can be categorized by the critical dimension 312 and the relative position of the main features 304. For each main feature 304, variables such as the position 320 and the width 318 of the auxiliary features 306 surrounding the main feature 304, and the pattern bias 314 are determined empirically by printing different combinations of these variables. The results that maximize the intensity log-slope (ILS) and depth-of-focus of features formed in a photoresist of a substrate based on the digital pattern file 104 are recorded as one row in the lookup table. The process is repeated for different main feature 304 patterns to complete the table. The process can be further extended to describe non-1D main features 304, such as the mask patterns 400 shown in FIGS. 4C and 4D.

In operation, when the lookup table is constructed, the virtual mask software application 102 analyzes each main feature 304 on the digital pattern file 104 and determines the critical dimension 312 and the polygon spacing 322. If there are different critical dimensions 312 or polygon spacings 322 along a main feature edge 308, the edge is broken into segments with constant critical dimensions 312 and polygon spacing 322. The pattern modification software application 106 references the lookup table to determine the position 320 and the width 318 of the auxiliary features 306 based on inputs of the critical dimension 312 and the polygon spacing 322. The pattern modification software application 106 utilizes the lookup table to determine the pattern bias 314. The lookup table includes empirical data relating to the biasing required to maintain a critical dimension 312 for the main features 304 based on the position 320 and the width 318 of the auxiliary features 306.

In embodiments where the main features 304 are not repeated, the lookup table can be expanded to include the critical dimension 312 of the adjacent main feature 304 as the 3rd input value (3rd attribute) to the lookup table. For example, a main feature 304 with a critical dimension 312 of 2 μm is adjacent to a main feature 304 with a critical dimension 312 of 4 μm. As the main features 304 become more complicated, more input attributes can be added to better describe the main features 304.

The rule-based algorithm 606 references the lookup table to determine a position 320 and a width 318 of the auxiliary features 306 that maximizes an intensity log-slope (ILS) and depth-of-focus of features formed in a photoresist of a substrate based on the digital pattern file 104. The rule-based algorithm 606 also ensures that the auxiliary features 306 meet a threshold of distance between each adjacent auxiliary feature 306 as well as the distance between the auxiliary features and the main features 304. The threshold of distance assists in ensuring that the auxiliary features 306 will not be printed. Additionally, the rule-based algorithm 606 ensures that the auxiliary features 306 have a width 318 less than the critical dimension 312 of the main features 304 such that the auxiliary features 306 will not be printed. The rule-based algorithm ensures that the pattern bias 314 is applied such that the main feature 304 is within tolerances of the desired pattern based on the digital pattern file 104. In one embodiment, which can be combined with other embodiments described herein, the ILS is specifically refined along the main feature edges 308 of the main feature 304. The auxiliary features 306 of more than one polygon of the digital pattern file 104 may be determined.

At operation 503, the mask pattern 300 of the digital pattern file 104 is provided to a virtual mask software application 102. The mask pattern 300 includes the data corresponding to the main features 304 with the pattern bias 314 as well as the data corresponding to the position 320 and the width 318 of the auxiliary features 306. The virtual mask software application 102 converts the mask pattern 300 within the digital pattern file 104 to one or more quadrilateral polygons to generate a virtual mask file. The virtual mask file is a digital representation of the main features 304 and the auxiliary features 306.

At operation 504, the virtual mask file is delivered to the maskless lithography device 108. The maskless lithography device 108 performs a lithography process to expose a substrate to form the main features 304 included in the virtual mask file. The auxiliary features 306 are not printed. Optionally, after the lithography process of operation 504, the substrate may be further processed, for example by development of the photoresist and/or etching, to form a pattern on the substrate.

The main features 304 with the auxiliary features 306 construct a 180-degree phase interference between the auxiliary features 306 and the main feature edge 308 of the main features 304. Therefore, increasing the intensity log-slope and depth-of-focus of the features formed on the photoresist of the substrate. Thus, the resolution and the process window of the maskless lithography device 108 are improved.

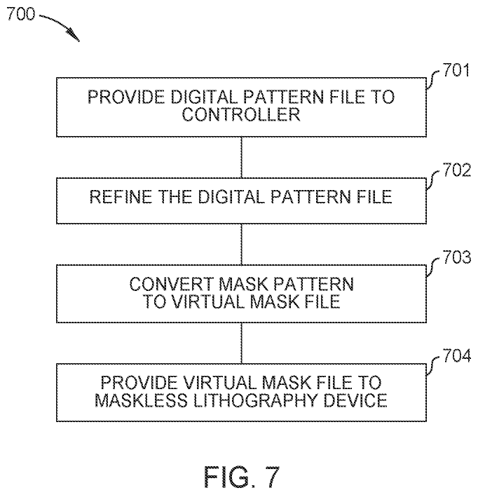

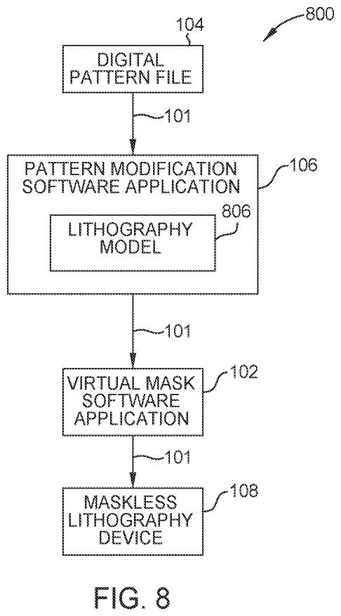

FIG. 7 is a flow diagram of a method 700 for performing a model based double exposure as shown in FIG. 7. FIG. 8 is a schematic view of a model based process flow 800. FIG. 7 includes elements of the lithography environment 100 shown in FIG. 1. To facilitate explanation, the method 700 will be described with reference to the model based process flow 800 of FIG. 8 and the mask pattern 300 of FIGS. 3A and 3B. In one embodiment, which can be combined with other embodiments described herein, the method 700 may be utilized with any lithography process and any maskless lithography device. The controller 110 is operable to facilitate the transfer of a digital pattern file 104 (e.g., data). The controller 110 is operable to facilitate operations of the method 700.

At operation 701, a digital pattern file 104 is provided to a controller 110. The controller 110 is operable to execute a pattern modification software application 106. The digital pattern file 104 corresponds to a pattern to be written into a photoresist using electromagnetic radiation output by the maskless lithography device 108 (shown in FIG. 2). The digital pattern file 104 may include areas of interest which correspond to one or more structural elements. The structural elements may be constructed as geometrical shapes, such as polygons (e.g., polygons 302A and 302B shown in FIGS. 3A-3B). The digital pattern file 104 initially defines one or more main features 304 (shown in FIGS. 3A-3B).

At operation 702, the digital pattern file 104 is refined with the pattern modification software application 106. The digital pattern file 104 is refined to determine the position 320 and width 318 of one or more auxiliary features 306 and a pattern bias 314 of the main features 304. The digital pattern file 104 is refined to improve the intensity-log-slope (ILS) of features to be formed on a photoresist in a lithography process. In one embodiment, which can be combined with other embodiments described herein, the ILS is specifically refined along main feature edges 308 of the main features 304.

The width 318 and the position 320 of the auxiliary features 306 as well as the pattern bias 314 of the main feature 304 are determined based on a lithography model 806. The lithography model 806 is operable to predict the position 320 and the width 318 of the auxiliary features 306 and predict the pattern bias 314 of the main features 304. The lithography model is constructed to be defined based on optical properties (e.g., optical properties relating to the maskless lithography device 108) and the photoresist properties (e.g., properties of the photoresist of which the pattern will be printed on such as materials and processing characteristics of the photoresist).

Upon construction of the lithography model, the digital pattern file 104 is input to the lithography model. The lithography model will then predict and adjust variables to output a prediction of the aerial image and resist profile of the digital pattern file 104. Through post-processing steps, the ILS and depth of focus of features formed in a photoresist of a substrate based on the digital pattern file 104 may be determined. The variables includes a width 318 and position 320 of auxiliary features 306 (shown in FIGS. 3A and 3B) and a pattern bias value of the main features 304 (shown in FIG. 3B). The variables are predicted by the lithography model such that the ILS is increased, the depth of focus is increased, desired dimensions for the main features 304 are maintained, and no extra patterns are printed. The method 700 is not limited to iterative methods to solve the lithography model and other mathematical methods can be used to solve the lithography model.

The variables are adjusted according to the lithography model 806 or other rules of the pattern modification software application 106 until a threshold intensity log-slope (ILS) and/or depth-of-focus of features are achieved. Additionally or alternatively, the pattern modification software application 106 refines the digital pattern file 104 by adjusting the variables of the digital pattern file 104 according to the lithography model 806 or other rules of the pattern modification software application 106 until a maximum intensity log-slope (ILS) and/or depth-of-focus of features are achieved. In one embodiment, which can be combined with other embodiments described herein, the ILS is specifically refined along the main feature edges 308 of the main features 304.

The pattern modification software application 106 may determine the position 320 of the auxiliary features 306, the width 318 of the auxiliary features 306, and the pattern bias 314 of the main features 304 simultaneously within the pattern modification software application 106. For example, the pattern modification software application 106 may be able to adjust the position 320 and the width 318 in concert with the pattern bias 314 to refine the auxiliary features 306. The pattern modification software application 106 predicts the pattern bias 314 required to maintain a critical dimension 312 for the main features 304 based on the position 320 and the width 318 of the auxiliary features 306.

The lithography model 806 ensures that the pattern bias 314 is determined such that the main features 304 are within tolerances of the desired pattern based on the digital pattern file 104. The lithography model 806 also ensures that the auxiliary features 306 meet a threshold of distance between each adjacent auxiliary feature 306 as well as the distance between the auxiliary features and the main features 304. The threshold of distance assists in ensuring that the auxiliary features 306 will not be printed. Additionally, the rule-based algorithm 606 ensures that the auxiliary features 306 have a width 318 less than the critical dimension 312 of the main features 304 such that the auxiliary features 306 will not be printed. The digital pattern file 104 is refined and updated by the pattern modification software application 106 to form a mask pattern 300.

At operation 703, the mask pattern 300 of the digital pattern file 104 is provided to a virtual mask software application 102. The mask pattern 300 includes the data corresponding to the main features 304 with the pattern bias 314 as well as the data corresponding to the position 320 and the width 318 of the auxiliary features 306. The virtual mask software application 102 converts the mask pattern 300 within the digital pattern file 104 to one or more quadrilateral polygons to generate a virtual mask file. The virtual mask file is a digital representation of the main features 304 and the auxiliary features 306.

At operation 704, the virtual mask file is delivered to the maskless lithography device 108. The maskless lithography device 108 performs a lithography process to expose a substrate to form the main features 304 included in the virtual mask file. The auxiliary features 306 are not printed. Optionally, after the lithography process of operation 704, the substrate may be further processed, for example by development of the photoresist and/or etching, to form a pattern on the substrate.

The main features 304 with the auxiliary features 306 construct a 180-degree phase interference between the auxiliary features 306 and the main feature edge 308 of the main features 304. Therefore, increasing the intensity log-slope and depth-of-focus of the features formed on the photoresist of the substrate. Thus, the resolution and the process window of the maskless lithography device 108 are improved.

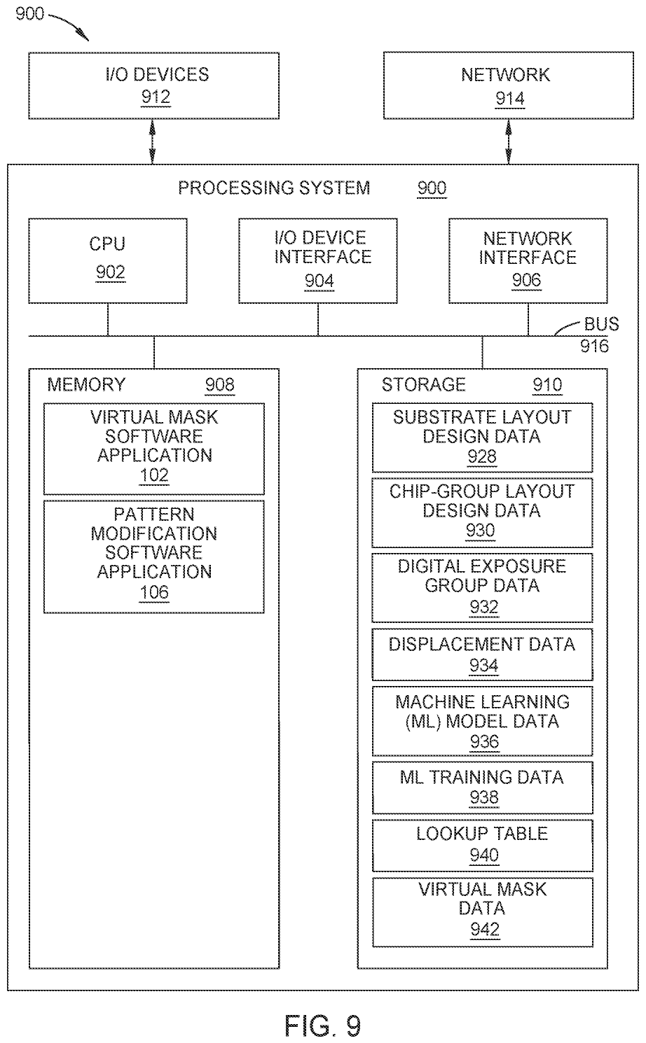

FIG. 9 depicts a processing system 900, according to certain embodiments. Processing system 900 is an example of controller 110, according to certain embodiments, and may be used in place of controller 110 described above. FIG. 9 depicts an example processing system 900 that may operate embodiments of systems described herein to perform embodiments according to the flow diagrams and methods described herein, such as the method for performing a rule-based exposure as described with respect to FIGS. 5 and 6 and the method for performing a model based exposure described with respect to FIGS. 7 and 8.

Processing system 900 includes a central processing unit (CPU) 902 connected to a data bus 916. CPU 902 is configured to process computer-executable instructions, e.g., stored in memory 908 or storage 910, and to cause the processing system 900 to perform embodiments of methods described herein on embodiments of systems described herein, for example with respect to FIGS. 1-8. CPU 902 is included to be representative of a single CPU, multiple CPUs, a single CPU having multiple processing cores, and other forms of processing architecture capable of executing computer-executable instructions.

Processing system 900 further includes input/output (I/O) device(s) 912 and interfaces 904, which allows processing system 900 to interface with input/output devices 912, such as, for example, keyboards, displays, mouse devices, pen input, and other devices that allow for interaction with processing system 900. Note that processing system 900 may connect with external I/O devices through physical and wireless connections (e.g., an external display device).

Processing system 900 further includes a network 914 interface, which provides processing system with access to external network 914 and thereby external computing devices.

Processing system 900 further includes memory 908, which in this example includes a virtual mask software application 102 and a pattern modification software application 106 for performing operations described herein, for example as described in connection with FIGS. 5 and 7.

Note that while shown as a single memory 908 in FIG. 9 for simplicity, the various aspects stored in memory 908 may be stored in different physical memories, including memories remote from processing system 900, but all accessible by CPU 902 via internal data connections such as bus 916.

Storage 910 further includes substrate layout design data 928, chip-group layout design data 930, digital exposure group data 932, displacement data 934, machine learning (ML) model data 936 (i.e., lithography model data), ML training data 938, lookup table data 940, and virtual mask data 942, for performing operations described herein. As would be appreciated by one of ordinary skill, other data and aspects may be included in storage 910.

As with memory 908, a single storage 910 is depicted in FIG. 9 for simplicity, but various aspects stored in storage 910 may be stored in different physical storages, but all accessible to CPU 902 via internal data connections, such as bus 916, or external connection, such as network interfaces 906. One of skill in the art will appreciate that one or more elements of processing system 900 may be located remotely and accessed via a network 914.

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a c c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more operations or actions for achieving the methods. The method operations and/or actions may be interchanged with one another without departing from the scope of the claims. In other words, unless a specific order of operations or actions is specified, the order and/or use of specific operations and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

In summation, methods of printing features within a lithography environment are described herein. The methods include determining a mask pattern. The mask pattern includes auxiliary features to be provided with main features to a maskless lithography device in a lithography process. The auxiliary features are determined with a rule-based process flow or a lithography model process flow. Additionally, a bias for the main features may be implemented to compensate for variations of critical dimensions of the main features due to the auxiliary features. The mask pattern is formulated by a pattern modification pattern software application such that an intensity log-slope and depth-of-focus are improved for features to be formed in a photoresist based on the mask pattern. Therefore, the mask pattern is operable to improve resolution and the process window of a maskless lithography device utilized in the lithography process. The determining the mask pattern is a software based solution and thus can be utilized quickly and cost effectively to improve the resolution and the process window.

While the foregoing is directed to examples of the present disclosure, other and further examples of the disclosure may be devised without departing from the basic scope thereof, and the scope thereof is determined by the claims that follow.

What is claimed is:

1. A method, comprising:
receiving data defining one or more main features for a lithographic process, the main features including one or more polygons;
determining a position and a width of one or more auxiliary features based on the data defining the main features;
determining a pattern bias to be applied for the main features during the lithographic process, the pattern bias of the main features determined based on the position and the width of the auxiliary features;
converting the data corresponding to the main features, the auxiliary features, and the pattern bias to a virtual mask file; and
patterning a substrate using the virtual mask file in a maskless lithography device.

2. The method of claim 1, wherein the determining the position and the width of the auxiliary features includes referencing a lookup table, the lookup table including empirical data relating to the main features.

3. The method of claim 2, wherein the lookup table determines the position and the width of the auxiliary features based on a maximum of one or both of an intensity log-slope (ILS) and depth-of-focus of the main features formed in a photoresist of a substrate based on the data.

4. The method of claim 3, wherein the lookup table determines the position of the auxiliary features such that the auxiliary features meet a threshold of distance between each adjacent auxiliary feature and a threshold distance between the auxiliary features and the main features.

5. The method of claim 1, wherein the determining the pattern bias includes referencing a lookup table, the lookup table including empirical data relating to biasing for maintaining a predefined critical dimension for the main features.

6. The method of claim 1, further comprising processing the substrate by developing or etching the substrate to form a pattern on the substrate.

7. The method of claim 1, wherein the converting the data of the main features and the data indicating the pattern bias to the virtual mask file includes converting each of the one or more polygons within the data to one or more quadrilateral polygons to generate the virtual mask file.

8. The method of claim 1, wherein the width of the auxiliary features is less than a critical dimension of the main features.

9. The method of claim 1, wherein the auxiliary features construct a 180-degree phase interference between the auxiliary features and a main feature edge of the main features.

10. A method, comprising:
receiving data defining one or more main features for a lithographic process, the main features including one or more polygons;
inputting the data to a lithography model constructed to predict an aerial image and resist profile based on the data;
determining a position and a width of one or more auxiliary features using numerical calculations to solve the lithography model, wherein the position and the width determined correspond to a maximum intensity log-slope (ILS) or depth-of-focus of the main features formed in a photoresist of a substrate based on the data;
determining a pattern bias to be applied for the main features during the lithographic process, the pattern bias of the main features determined using numerical calculations to solve the lithography model, wherein the pattern bias determined corresponds to a maximum ILS or depth-of-focus of the main features formed in the photoresist of the substrate based on the data;
converting the data corresponding to the main features, the auxiliary features, and the pattern bias to a virtual mask file; and
patterning a substrate using the virtual mask file in a maskless lithography device.

11. The method of claim 10, wherein the determining the position of the auxiliary features, the width of the auxiliary features, and the pattern bias includes providing inputs to the lithography model of a pattern modification software application, the pattern modification software application operable to form a mask pattern with the main features and the auxiliary features.

12. The method of claim 11, wherein the pattern modification software application predicts the pattern bias required to maintain a critical dimension for the main features based on the position and the width of the auxiliary features.

13. The method of claim 10, wherein the width of the auxiliary features is less than a critical dimension of the main features.

14. The method of claim 10, further comprising processing the substrate by developing or etching the substrate to form a pattern on the substrate.

15. The method of claim 10, wherein the converting the data of the main features and the data indicating the pattern bias to the virtual mask file includes converting each of the one or more polygons within the data to one or more quadrilateral polygons to generate the virtual mask file.

16. The method of claim 10, wherein the auxiliary features construct a 180-degree phase interference between the auxiliary features and a main feature edge of the main features.

17. A system, comprising:
a moveable stage configured to support a substrate having a photoresist disposed thereon; and
a processing unit disposed over the moveable stage configured to print a virtual mask file provided by a controller in communication with the processing unit, wherein the controller is configured to:
receive data defining one or more main features for a lithographic process, the main features including one or more polygons;
determine a position and a width of one or more auxiliary features based on the data defining the main features;
determine a pattern bias to be applied for the main features during the lithographic process, the pattern bias of the main features determined based on the position and the width of the auxiliary features;
convert the data corresponding to the main features, the auxiliary features, and the pattern bias to the virtual mask file; and
pattern a substrate using the virtual mask file with the processing unit.

18. The system of claim 17, wherein the controller is further configured to process the substrate by developing or etching the substrate to form a pattern on the substrate.

19. The system of claim 17, wherein the width of the auxiliary features is less than a critical dimension of the main features.

20. The system of claim 17, wherein the controller is further configured to reference a lookup table, the lookup table including empirical data relating to the main features.
